(19) United States
(12) Patent Application Publication
(10) Pub. No.: US 2003/0230796 A1
(43) Pub. Date: Dec. 18, 2003

(54) Stacked die semiconductor device

(76) Inventors: Aminuddin Ismail, Shah Alam (MY); Lan Chu Tan, Klang (MY); Kong Bee Tiu, Port Klang (MY); Cheng Choi Yong, Kuala Lumpur (MY)

Correspondence Address: Motorola, Inc., Mail Drop PL02, 7700 West Parmer Lane, Austin, TX, 78729, US

(21) Appl. No.: 10/167,824

(22) Filed: Jun. 12, 2002

(51) Int. Cl. H01L 21/48; H01L 23/48; H01L 29/40

(52) U.S. Cl. 257/686; 257/685; 438/109; 257/737; 257/738; 438/613; 257/777; 438/617

(57) ABSTRACT

An electrical connection for connecting multiple bonding pads of different devices. The electrical connection includes a first bonding pad on a first device and a bump disposed on the first bonding pad. A first wire is stitch bonded to the bump on the first device and electrically connected to a bonding pad of a second device. A second wire is ball bonded to the stitch bond of the first wire. The second wire is also electrically connected to a bonding pad of a third device. Thus, the second and third devices are connected to a single bonding pad of the first device. The size of the bonding pad is not unnecessarily increased to accommodate multiple wire bonds. Further, additional wires may be stitch bonded between the first stitch bond and the ball bond.

### BACKGROUND OF THE INVENTION

The present invention relates to interconnects of integrated circuits and a method of connecting stacked integrated circuits.

An integrated circuit (IC) die is a small device formed on a semiconductor wafer, such as a silicon wafer. Such a die is typically cut from the wafer and attached to a substrate or base carrier for interconnect redistribution. Bond pads on the die are then electrically connected to the leads on the carrier via wire bonding. The die and wire bonds are then encapsulated with a protective material such that a package is formed. The leads encapsulated in the package are redistributed in a network of conductors within the carrier and end in an array of terminal points outside the package. The terminal points allow the die to be electrically connected with other circuits, such as on a printed circuit board.

With the goal of increasing the amount of circuitry in a package, but without increasing the area of the package so that the package does not take up any more space on the circuit board, manufacturers have been stacking two or more die within a single package. Such devices are sometimes referred to as stacked multichip packages.

Referring to FIG. 1, an enlarged partial side view of a conventional stacked multichip package 10 is shown. The package 10 includes a top die 12, a bottom die 14 and a substrate 16. The top and bottom dice 12, 14 are electrically connected to the substrate 16 with wires via a wirebonding process. It is common to connect the top die 12 directly to the substrate 16 with long wires (not shown) and the bottom die 14 to the substrate 16 with shorter wires. However, some pads need to be bonded down from the top die 12 to the bottom die 14 then to the substrate 16.

FIG. 2 is an enlarged top view of a bond pad 22 that can accept two wires and FIG. 3 is an enlarged side view of the bond pad 22 to which wires 18, 20 have been wirebonded with ball bonds 24. In order to accept two wires, the bond pad 22 is elongated. The pad 22 must be elongated not only to accept the two wires, but also so that the capillary (used to perform wirebonding) doesn't hit the first wirebond when the second wirebond is being performed. Unfortunately, having to provide an elongated bond pad can increase the size of the die.

It would be advantageous to be able to connect two or more wires to a bond pad of a die without having to increase the size of the bond bad.

### BRIEF DESCRIPTION OF THE DRAWINGS

The foregoing summary, as well as the following detailed description of preferred embodiments of the invention, will be better understood when read in conjunction with the appended drawings. For the purpose of illustrating the invention, there is shown in the drawings embodiments that are presently preferred. It should be understood, however, that the invention is not limited to the precise arrangements and instrumentalities shown. In the drawings:

FIG. 1 is an enlarged side view of a conventional stacked multichip package;

FIG. 2 is an enlarged top view of a conventional bonding pad that accepts two wires;

FIG. 3 is an enlarged side view of the bonding pad of FIG. 2 with two wires connected thereto via ball bonding;

FIG. 4 is an enlarged partial side view of an embodiment of a stacked multichip package in accordance with the present invention;

FIG. 5 is an enlarged side view of a bond pad having two wires connected thereto in accordance with the present invention; and

FIG. 6 is an enlarged side view of a bond pad having multiple wires connected thereto in accordance with the present invention.

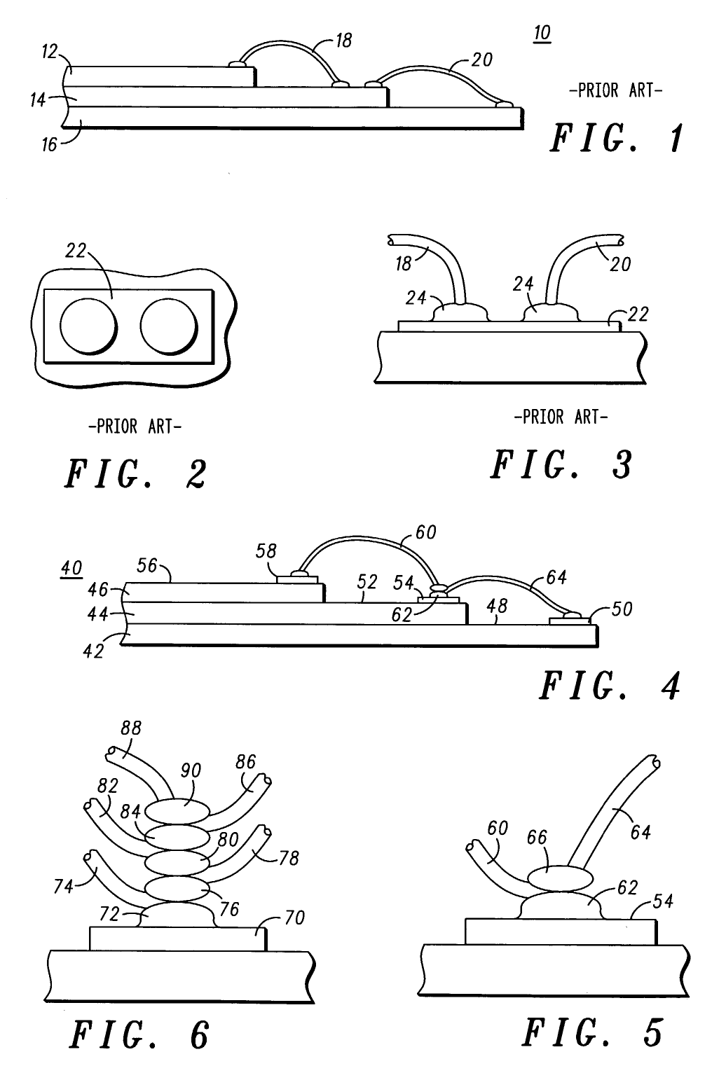

### DETAILED DESCRIPTION OF PREFERRED EMBODIMENTS

The detailed description set forth below in connection with the appended drawings is intended as a description of the presently preferred embodiments of the invention, and is not intended to represent the only forms in which the present invention may be practiced. It is to be understood that the same or equivalent functions may be accomplished by different embodiments that are intended to be encompassed within the spirit and scope of the invention. For simplicity, examples used to illustrate the invention refer only to a stacked die package having two stacked dice. However, the same invention in fact can be applied to other types of packages and to stacked die packages having more than two stacked dice.

Certain features in the drawings have been enlarged for ease of illustration and the drawings and the elements thereof are not necessarily in proper proportion. However, those of ordinary skill in the art will readily understand such details. In the drawings, like numerals are used to indicate like elements throughout.

The present invention is an electrical connection for connecting a plurality of bonding pads. The connection includes a first bonding pad and a bump disposed on the first bonding pad. A first wire is stitch bonded to the bump and a second wire ball is bonded to the stitch bond of the first wire.

The present invention also provides a stacked multichip package having a base carrier, a bottom integrated circuit die and a top integrated circuit die. The base carrier has a top side including a plurality of first bonding pads. The bottom integrated circuit die has a bottom surface attached to the base carrier top side, and an opposing, top surface having a plurality of second bonding pads. The top integrated circuit die has a bottom surface attached to the top surface of the bottom die, and a top surface having a plurality of third bonding pads. A first one of the third bonding pads is electrically connected to a first one of the second bonding pads with a first wire by way of a bump on the first one of the second bonding pads, and a first one of the first bonding pads is electrically connected to the first one of the second bonding pads with a second wire. The first wire is stitch bonded to the bump and the second wire is ball bonded to the stitch bond.

The present invention also provides a stacked multichip package including a base carrier having a top side with a plurality of first bonding pads, a bottom integrated circuit die having a bottom surface attached to the base carrier top side, and an opposing, top surface having a plurality of second bonding pads, and a top integrated circuit die having a bottom surface attached to the top surface of the bottom die, and a top surface having a plurality of third bonding pads. A first electrically conductive bump is disposed on a first one of the second bonding pads. A first wire electrically connects a first one of the third bonding pads to the first one of the second bonding pads by way of the first bump. The first wire is stitch bonded to the first bump with a first stitch bond. A second wire electrically connects a first one of the first bonding pads to the first one of the second bonding pads. The second wire is ball bonded to the first stitch bond.

The present invention also provides a method of electrically connecting a plurality of devices, where each device has a plurality of bonding pads. The method includes the steps of:

disposing a first electrically conductive bump on a first bonding pad of a first device;

stitch bonding a first wire to the first bump with a first stitch bond; and

ball bonding a second wire to the first stitch bond.

Referring now to FIG. 4, a partial side view of an embodiment of a stacked multichip package 40 in accordance with the present invention is shown. The stacked multichip package 40 includes a base carrier or substrate 42, a bottom integrated circuit die 44 and a top integrated circuit die 46. The substrate 42 provides an interconnect network for electrically connecting the bottom and top dice 44 and 46 to each other and to other components or devices.

The base carrier 42 has a top side 48 including a plurality of first bonding pads 50. The bottom integrated circuit die 44 has a bottom surface attached to the base carrier top side 48, and an opposing, top surface 52. The top surface 52 includes a plurality of second bonding pads 54. The top integrated circuit die 46 has a bottom surface attached to the top surface 52 of the bottom die 44, and a top surface 56 having a plurality of third bonding pads 58. The base carrier 42, bottom die 44, and top die 46 are of a type known to those of ordinary skill in the art and detailed descriptions thereof are not necessary for a full understanding of the invention.

As is known to those of ordinary skill in the art, the base carrier 42, bottom die 44 and top die 46 are electrically connected with wires wirebonded to the various bonding pads 50, 54 and 58. According to the present invention, multiple wires may be connected to a single bonding pad by stacking the wirebonds in a bump-stitch-ball type sandwich as described below.

As shown in FIG. 4, a first one of the third bonding pads 58 is electrically connected to a first one of the second bonding pads 54 with a first wire 60 by way of a bump 62 on the first one of the second bonding pads 54, and a first one of the first bonding pads 50 is electrically connected to the first one of the second bonding pads 54 with a second wire 64. The first wire 60 is stitch bonded to the bump 62 and the second wire 64 is ball bonded to the stitch bond. Of course, it will be understood that the second wire 64 from the first one of the first bonding pads 50 could be stitch bonded to the bump 62 on the first one of the second bonding pads 54 and the first wire 60 from the first one of the third bonding pads 58 could be ball bonded to the stitch bond.

The term ‘wirebonding’ is generally accepted to mean the interconnection, via wire, of chips and substrates. The most frequently used methods of joining the wires to the pads is via either thermosonic or ultrasonic bonding. Ultrasonic wirebonding uses a combination of vibration and force to rub the interface between the wire and the bond pad, causing a localized temperature rise that promotes the diffusion of molecules across the boundary. Thermosonic bonding, in addition to vibration, uses heat, which further encourages the migration of materials. In ball bonding, a capillary holds the wire. A ball formed on one end of the wire is pressed against the face of the capillary. The ball may be formed with a hydrogen flame or a spark. The capillary pushes the ball against the bond pad, and then, while holding the ball against the first pad, ultrasonic vibration is applied, which bonds the ball to the die. Once the ball is bonded to the die, the capillary, which is still holding the wire, is moved over a second bonding pad to which the first pad is to be electrically connected. To form a stitch bond, the wire is pressed against the second pad, forming a wedge-shaped bond. Once again, ultrasonic energy is applied until the wire is bonded to the second pad. The capillary is then lifted off the bond, breaking the wire. Both stitch bonding and ball bonding are well known by those of skill in the art.

Referring now to FIG. 5, an enlarged side view of the second bond pad 54 having the first and second wires 60, 64 connected thereto in accordance with the present invention is shown. FIG. 5 highlights the electrical connection for connecting ones of the first, second and third bonding pads. The bump 62 may be larger, smaller, or the same size as the ball 66 and in most cases, will probably be the same size as the ball 66 as they are formed in a similar manner. However, in one embodiment of the invention, the bump 62 is bigger than the ball 66 of the ball bond to ensure that the ball 66 and the stitch bond sit completely on the bump 62. The diameter of the bump 62 and the ball 66 depend in large part on the diameter of the wire from which they are formed. For example, for 25 um (1 mil) wire, the bump 62 can be controlled to be between about 48-55 um and the ball 66 will be between about 45-55 um. In one embodiment of the invention, a 20 um gold wire was wirebonded to a 76 um×76 um pad. The bump formed on the pad was about 42 um and the ball had a diameter of about 35 um.

The wires 62, 64 may be formed of any electrically conductive metal or combination of metals, such as are known by those of skill in the art. Suitable bond wires typically comprise a conductive metal such as copper or gold and may be either fine wires (<50 um in diameter) or heavy wires (>50 um in diameter). The bump 62 preferably comprises the same materials as the wires 62, 64 and is formed or disposed on the bonding pad in the same manner that the ball bond is formed, such as with a hydrogen flame or a high voltage electrical spark. More particularly, a ball is formed on one end of the wire in the wirebonder. The formed ball is pressed against the face of the wirebonder capillary. The capillary pushes the ball against the die bond pad, and then, while holding the ball against the pad, ultrasonic vibration is applied, which bonds the ball to the die pad. Once the ball is bonded to the die pad, the wire above the bonded ball 62 is cut-off by clamping the wire above the capillary while the capillary is being lifted up. The wire area above the ball, which is the weakest spot, will give way, leaving only the bump 62. In short the bump 62 is formed as if a full bond cycle for first bond (the ball) and the stitch was completed but no wire looping was performed in between the ball and stitch bond.

FIG. 6 is an enlarged side view of a bond pad 70 having multiple wires connected thereto in accordance with the present invention. More particularly, the bond pad 70 has a first bump 72 disposed on its surface. A first wire 74 is stitch bonded to the first bump 72 with a first stitch bond. A second bump 76 is formed on the first stitch bond. A second wire 78 is stitch bonded to the second bump 76 with a second stitch bond. A third bump 80 is formed on the second stitch bond and a third wire 82 is stitch bonded on the third bump 80 with a third stitch bond. A fourth bump 84 is then formed on the third stitch bond and a fourth wire 86 is stitch bonded to the fourth bump 84 with a fourth stitch bond. A fifth wire 88 is then ball bonded on the fourth stitch bond with a ball bond 90. All of the bumps 72, 76, 82 and 84 are generally of the same size, as wirebonding machines are capable of high accuracy. Current wirebonders are also capable of keeping the bumps on center. The bumps 72, 76, 80 and 84 are formed of the same material as the wires 74, 78, 82, 86 and 88 and disposed on the pad 70 and stitch bonds, respectively, with the wirebonder as described above, using a hydrogen flame or a spark. No modifications to the capillary are required.

The present invention further provides a method of electrically connecting a plurality of devices, where each of the devices has a plurality of bonding pads. The method includes the steps of disposing a first electrically conductive bump on a first bonding pad of a first device, stitch bonding a first wire to the first bump with a first stitch bond, and then ball bonding a second wire to the first stitch bond. Further wires may also be stitch bonded between the first stitch bond and the ball bond. For example, a third wire may be electrically connected to the bonding pad by disposing a second electrically conductive bump on the first stitch bond and stitch bonding the third wire to the second bump with a second stitch bond. The second wire is then ball bonded to the second stitch bond. The sandwich (bump-stitch-ball) type interconnects formed with the foregoing method have been found to provide stronger bonds than a single stitch bond. Wire pull and wire peel have been within desired tolerances.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. For example, the present invention is not limited to a package with two stacked dice, but can be applied to a package with multiple stacked dice. Further, the present invention is not limited to stacked devices, but is applicable to all wire bonded package types, including but not limited to BGA, QFN, QFP, PLCC, CUEBGA, TBGA, and TSOP. The present invention can be applied in other applications, such as to replace a very long wire used to connect two distant bond pads. That is, to replace a very long wire where two bonds to one pad is required. It is understood, therefore, that this invention is not limited to the particular embodiments disclosed, but covers modifications within the spirit and scope of the present invention as defined by the appended claims.

1. An electrical connection for connecting a plurality of bonding pads, the connection comprising:
a first bonding pad;
a bump disposed on the first bonding pad;
a first wire stitch bonded to the bump; and
a second wire ball bonded to the stitch bond of the first wire.

2. The electrical connection of claim 1, wherein the bump is larger than a ball of the second wire ball bond.

3. The electrical connection of claim 2, wherein the bump has a diameter of between about 48-55 um and the ball has a diameter of about 45-55 um.

4. The electrical connection of claim 1, wherein the ball and the stitch sit completely on the bump.

5. The electrical connection of claim 1, wherein the ball, the bump and the first and second wires are the same material.

6. The electrical connection of claim 1, wherein the ball, the bump and the first and second wires comprise gold.

7. A stacked multichip package, comprising:
a base carrier having a top side including a plurality of first bonding pads;
a bottom integrated circuit die having a bottom surface attached to the base carrier top side, and an opposing, top surface, the top surface including a plurality of second bonding pads; and
a top integrated circuit die having a bottom surface attached to the top surface of the bottom die, and a top surface having a plurality of third bonding pads,
wherein a first one of the third bonding pads is electrically connected to a first one of the second bonding pads with a first wire by way of a bump on the first one of the second bonding pads, and a first one of the first bonding pads is electrically connected to the first one of the second bonding pads with a second wire, wherein the first wire is stitch bonded to the bump and the second wire is ball bonded to the stitch bond.

8. The stacked multichip package of claim 7, wherein the ball and the stitch sit completely on the bump.

9. The electrical connection of claim 7, wherein the ball, the bump and the wires comprise the same material.

10. The electrical connection of claim 9, wherein the ball, the bump and the wires comprise gold.

11. The stacked multichip package of claim 7, wherein the second wire connecting the first one of the first bonding pads is stitch bonded to the bump on the first one of the second bonding pads and the second wire connecting the first one of the third bonding pads is ball bonded to the stitch bond.

12. The stacked multichip package of claim 7, further comprising:
a second one of the third bonding pads being electrically connected to the first one of the second bonding pads with a third wire, wherein the third wire is stitch bonded to a second bump disposed on the first stitch bond, and the second wire is ball bonded to the stitch bond of the third wire.

13. A stacked multichip package, comprising:
a base carrier having a top side including a plurality of first bonding pads;
a bottom integrated circuit die having a bottom surface attached to the base carrier top side, and an opposing, top surface, the top surface including a plurality of second bonding pads;
a top integrated circuit die having a bottom surface attached to the top surface of the bottom die, and a top surface having a plurality of third bonding pads;
a first electrically conductive bump disposed on a first one of the second bonding pads;
a first wire electrically connecting a first one of the third bonding pads to the first one of the second bonding pads by way of the first bump on the first one of the second bonding pads, wherein the first wire is stitch bonded to the first bump with a first stitch bond; and
a second wire electrically connecting a first one of the first bonding pads to the first one of the second bonding pads, wherein the second wire is ball bonded to the first stitch bond.

14. The stacked multichip package of claim 13, wherein the second wire is stitch bonded to the first bump with a first stitch bond and electrically connects the first one of the first bonding pads to the first one of the second bonding pads, and the first wire is ball bonded to the first stitch bond, thereby electrically connecting the first one of the second bonding pads and the first one of the third bonding pads.

15. A method of electrically connecting a plurality of devices, each device having a plurality of bonding pads, comprising the steps of:
disposing a first electrically conductive bump on a first bonding pad of a first device;
stitch bonding a first wire to the first bump with a first stitch bond; and
ball bonding a second wire to the first stitch bond.

16. The method of electrically connecting a plurality of devices of claim 15, further comprising the steps of:
disposing a second electrically conductive bump on the first stitch bond; and
stitch bonding a third wire to the second bump with a second stitch bond, wherein the second wire is ball bonded to the second stitch bond.

17. The method of electrically connecting a plurality of devices of claim 15, wherein the first bump is larger than a ball of the second wire ball bond.

18. The method of electrically connecting a plurality of devices of claim 15, wherein the ball and the stitch bond sit completely on the bump.

19. The method of electrically connecting a plurality of devices of claim 15, wherein the ball, the bump and the wires comprise the same material.

20. The method of electrically connecting a plurality of devices of claim 19, wherein the material comprises gold.

21. The method of electrically connecting a plurality of devices of claim 15, wherein the first device comprises a first integrated circuit die, and the first wire electrically connects the first die to a second integrated circuit die.

22. The method of electrically connecting a plurality of devices of claim 21, wherein the second wire electrically connects the first die to a bonding pad of a base carrier.
